(19) United States
(12) Patent Application Publication
(10) Pub. No.: US 2025/0008846 A1
(43) Pub. Date: Jan. 2, 2025

(54) Methods for Fabricating Superconducting Integrated Circuits

(71) Applicant: 1372934 B.C. Ltd., Burnaby (CA)

(72) Inventors: Jed D. WHITTAKER, Vancouver (CA); Eric G. LADIZINSKY, Manhattan Beach, CA (US)

(21) Appl. No.: 18/444,266

(22) Filed: Feb. 16, 2024

Related U.S. Application Data
(60) Provisional application No. 63/448,723, filed on Feb. 28, 2023.

(51) Int. Cl. H10N 69/00; G06N 10/40; H10N 60/01; H10N 60/12; H10N 60/80

(52) U.S. Cl. CPC H10N 69/00; G06N 10/40; H10N 60/0912; H10N 60/12; H10N 60/805

(57) ABSTRACT

Superconducting integrated circuits and methods of forming superconducting integrated circuits are described. Methods include depositing an aluminum seed layer, depositing a layer of α-tantalum directly onto at least a portion of the aluminum seed layer, patterning the layer of α-tantalum, and depositing and patterning an overlying dielectric layer. Methods also include depositing a layer of β-tantalum and heating the β-tantalum to form α-tantalum and depositing a layer of aluminum and a layer of α-tantalum directly onto the layer of aluminum to act as a polish stop when polishing a dielectric layer.

### FIELD

This disclosure generally relates to superconducting integrated circuits and to methods for fabrication of superconducting integrated circuits, and in particular relates to systems and methods for forming components of superconducting integrated circuits using tantalum.

### BACKGROUND

### Quantum Devices

Quantum devices are structures in which quantum mechanical effects are observable. Quantum devices include circuits in which current transport is dominated by quantum mechanical effects. Such devices include spintronics and superconducting circuits. Both spin and superconductivity are quantum mechanical phenomena. Quantum devices can be used for measurement instruments, in computing machinery, and the like.

### Quantum Computation

A quantum computer is a system that makes direct use of at least one quantum-mechanical phenomenon, such as superposition, tunneling, and entanglement, to perform operations on data. The components of a quantum computer are qubits. Quantum computers can provide speedup for certain classes of computational problems such as computational problems simulating quantum physics.

### Superconducting Processor

A quantum processor may take the form of a superconducting processor. However, superconducting processors may include processors that are not intended for quantum computing. For instance, some implementations of a superconducting processor may not focus on quantum effects such as quantum tunneling, superposition, and entanglement but may rather operate by emphasizing different principles, such as the principles that govern the operation of classical computer processors. However, there may still be certain advantages to the implementation of such superconducting “classical” processors. Due to their natural physical properties, superconducting classical processors may be capable of higher switching speeds and shorter computation times than non-superconducting processors, and therefore it may be more practical to solve certain problems on superconducting classical processors. The present systems and methods are particularly well-suited for use in fabricating both superconducting quantum processors and superconducting classical processors.

### Superconducting Qubits

Superconducting qubits are a type of superconducting quantum device that may be included in a superconducting integrated circuit. Superconducting qubits may be separated into several categories depending on the physical property used to encode information. For example, superconducting qubits may be separated into charge, flux, and phase devices. Charge devices store and manipulate information in the charge states of the device. Flux devices store and manipulate information in a variable related to the magnetic flux through some part of the device. Phase devices store and manipulate information in a variable related to the difference in superconducting phase between two regions of the device. Recently, hybrid devices using two or more of charge, flux, and phase degrees of freedom have been developed. Superconducting qubits commonly include at least one Josephson junction. A Josephson junction is a small interruption in an otherwise continuous superconducting current path and is typically realized by a thin insulating barrier sandwiched between two superconducting electrodes. Thus, a Josephson junction may be formed as a three-layer or “trilayer” structure. Superconducting qubits are further described in, for example, U.S. Pat. Nos. 7,876,248; 8,035,540; and 8,098,179.

### Integrated Circuit Fabrication

An integrated circuit is also referred to in the present application as a chip, and a superconducting integrated circuit is also referred to in the present application as a superconducting chip.

Traditionally, the fabrication of superconducting integrated circuits has not been performed at state-of-the-art semiconductor fabrication facilities. This may be due to concern that some of the materials used in superconducting integrated circuits may contaminate the semiconductor facilities. For instance, gold may be used as a resistor in superconducting circuits, but gold may contaminate a fabrication tool used to produce complementary metal-oxide-semiconductor (CMOS) wafers in a semiconductor facility.

Superconductor fabrication has typically been performed in research environments where standard industry practices could be optimized for superconducting circuit production. Superconducting integrated circuits are often fabricated with tools that are traditionally used to fabricate semiconductor chips or integrated circuits. Due to issues unique to superconducting circuits, not all semiconductor processes and techniques are necessarily transferrable to superconductor chip manufacture. Transforming semiconductor processes and techniques for use in superconductor chip and circuit fabrication often requires changes and fine adjustments. Such changes and adjustments typically are not obvious and may require a great deal of experimentation. The semiconductor industry faces problems and issues not necessarily related to the superconducting industry. Likewise, problems and issues that concern the superconducting industry are often of little or no concern in standard semiconductor fabrication.

Any impurities within superconducting chips may result in noise which may compromise or degrade the functionality of the superconducting chip. Noise may also compromise or degrade the functionality of individual devices such as superconducting qubits. Since noise is a serious concern to the operation of quantum computers, measures should be taken to reduce noise wherever possible.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

According to an aspect, there is provided a method to form a superconducting integrated circuit comprising depositing a layer of aluminum, depositing a layer of α-tantalum directly onto at least a portion of the layer of aluminum, patterning the layer of α-tantalum and the layer of aluminum to form one or more superconducting traces, and depositing a dielectric layer.

According to other aspects, depositing a layer of aluminum may comprise depositing an aluminum seed layer, depositing a layer of α-tantalum may comprise depositing a layer of α-tantalum directly onto at least a portion of the aluminum seed layer at an ambient temperature, the method may further comprise depositing one or more additional aluminum seed layers, one or more α-tantalum layers, and one or more dielectric layers, and patterning the additional one or more aluminum seed layers, the additional one or more α-tantalum layers, and the additional one or more dielectric layers to form a portion of a quantum processor, the portion of a quantum processor comprising a plurality of qubits and a plurality of couplers, the method may further comprise patterning the dielectric layer, depositing a dielectric layer may comprise depositing a dielectric layer comprising one of: SiOₓ, SiNₓ, and a-Si, the method may further comprise polishing the dielectric layer to be flush with a top surface of the layer of a-tantalum, wherein the layer of α-tantalum acts as a polish stop, polishing the dielectric layer may comprise performing chemical-mechanical polishing, the method may further comprise depositing one or more additional aluminum layers, one or more α-tantalum layers, and one or more dielectric layers, and patterning the one or more additional aluminum layers, the one or more α-tantalum layers, and the one or more dielectric layers to form a quantum processor, the quantum processor comprising a plurality of qubits and a plurality of couplers.

According to an aspect, there is provided a method to form a superconducting integrated circuit comprising: depositing an aluminum seed layer; depositing a layer of α-tantalum to directly overlie at least a portion of the aluminum seed layer; patterning the layer of α-tantalum; depositing a dielectric layer to overlie at least a portion of the layer of α-tantalum; and patterning the dielectric layer.

According to other aspects, depositing an aluminum seed layer may comprise depositing an aluminum seed layer having a thickness greater than 5 nm, depositing a dielectric layer may comprise depositing a dielectric layer comprising one of: SiOₓ, SiNₓ, and α-Si, depositing a layer of α-tantalum directly onto at least a portion of the aluminum seed layer may comprise depositing a layer of α-tantalum directly onto at least a portion of the aluminum seed layer at an ambient temperature, and the method may further comprise depositing additional aluminum seed layers, α-tantalum layers, and dielectric layers; and patterning the additional aluminum seed layers, a-tantalum layers, and dielectric layers to form a quantum processor, the quantum processor comprising a plurality of qubits and a plurality of couplers.

According to an aspect, there is provided a superconducting integrated circuit comprising: a substrate; an aluminum seed layer overlying the substrate; an α-tantalum layer formed to directly overlie the aluminum seed layer; and a dielectric layer overlying the α-tantalum layer.

According to other aspects, the aluminum seed layer may have a thickness greater than 5 nm, the dielectric layer may comprise one of: SiOₓ, SiNₓ, and α-Si, and the α-tantalum layer may be patterned to form body wiring (e.g., electrically conductive traces) of one or more qubits or one or more couplers.

According to an aspect, there is provided a method to form a superconducting integrated circuit, the method comprising: depositing a layer of tantalum, the layer of tantalum comprising β-tantalum; heating the β-tantalum of the layer of tantalum to form α-tantalum; patterning the layer of tantalum; depositing a dielectric layer to overlie the layer of tantalum; and patterning the dielectric layer.

According to other aspects, heating the β-tantalum of the layer of tantalum to form α-tantalum may comprise depositing the layer of tantalum onto a surface having a temperature greater than 500° C. for sufficient time such that the β-tantalum is transformed into α-tantalum as the layer of tantalum is deposited, heating the β-tantalum of the layer of tantalum to form a-tantalum may comprise depositing the dielectric layer at a temperature greater than 500° C. for sufficient time such that the β-tantalum is transformed into α-tantalum in response to heating from the dielectric layer, heating the β-tantalum to form α-tantalum may comprise heating the β-tantalum to a temperature greater than 500° C. for sufficient time after depositing the layer of tantalum and prior to depositing the dielectric layer, the method may further comprise performing one or more measurements of the critical temperature to confirm that the β-tantalum has transformed into the α-tantalum, depositing a dielectric layer may comprise depositing a dielectric layer at a temperature in a range of 500° C. and 800° C. and may comprise depositing a dielectric layer comprising one of: SiOₓ, SiNₓ, and α-Si, and the method may further comprise depositing one or more additional tantalum layers and one or more dielectric layers; and patterning the one or more additional tantalum layers and one or more dielectric layers to form a quantum processor, the quantum processor comprising a plurality of qubits and a plurality of couplers.

According to an aspect, there is provided a quantum processor comprising a multi-layer superconducting integrated circuit, the multi-layer superconducting integrated circuit comprising: a substrate; a first α-tantalum layer overlying the substrate; a first dielectric layer overlying the first α-tantalum layer; and a second α-tantalum layer overlying the first α-tantalum layer; wherein at least one of the first α-tantalum layer and the second α-tantalum comprise body wiring of one or more qubits.

According to another aspect, at least one of the first α-tantalum layer and the second α-tantalum layer may comprise body wiring of one or more couplers.

According to an aspect, there is provided a method of forming a superconducting integrated circuit comprising: depositing a layer of aluminum; depositing a layer of α-tantalum directly onto the layer of aluminum; patterning the layer of α-tantalum and the layer of aluminum; depositing a dielectric layer; and polishing the dielectric layer, wherein the layer of α-tantalum acts as a polish stop.

According to other aspects, polishing the dielectric layer may comprise performing chemical-mechanical polishing (CMP), depositing a dielectric layer may comprise depositing a dielectric layer comprising one of: SiOₓ, SiNₓ, and α-Si, and the method may further comprise depositing one or more additional aluminum, α-tantalum, and dielectric layers; and patterning the one or more additional aluminum, α-tantalum, and dielectric layers to form a quantum processor, the quantum processor comprising a plurality of qubits and a plurality of couplers.

According to an aspect, there is provided a superconducting integrated circuit comprising: a tantalum wiring region comprising: one or more layers of tantalum wiring, each layer of tantalum wiring comprising a seed layer of aluminum and a layer of α-tantalum directly overlying the seed layer of aluminum; and one or more first layers of dielectric; an additional wiring region comprising: one or more layers of additional wiring, the additional wiring comprising a superconducting metal that is one of aluminum and niobium; and one or more second layers of dielectric; wherein the tantalum wiring region and the additional wiring region are separated by at least one third layer of dielectric, and at least one of the one or more layers of tantalum wiring and at least one of the one or more layers of additional wiring are in electrical communication with one another and collectively form at least one of a qubit and a coupler.

According to another aspect, the superconducting integrated circuit may further comprise one or more polish stop layers directly overlying the one or more layers of additional wiring.

According to an aspect, there is provided a superconducting integrated circuit comprising a tantalum wiring region comprising one or more aluminum layers, one or more layers of tantalum wiring, each layer of tantalum wiring comprising a layer of α-tantalum directly overlying a respective layer of aluminum, and one or more first layers of dielectric.

According to other aspects, the superconducting integrated circuit may further comprise an additional wiring region comprising one or more layers of additional wiring, the one or more layers of additional wiring comprising a superconducting metal that is one of aluminum and niobium, and one or more second layers of dielectric, and the tantalum wiring region and the additional wiring region may be separated by at least one third layer of dielectric, and at least one of the one or more layers of tantalum wiring and at least one of the one or more layers of additional wiring are in electrical communication with one another and collectively form at least one of a qubit and a coupler, the superconducting integrated circuit may further comprise one or more polish stop layers directly overlying the one or more layers of additional wiring, and the at least one of a qubit and a coupler may form a portion of a quantum processor.

In other aspects, the features described above may be combined in any reasonable combination as will be recognized by those skilled in the art.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements, and may have been solely selected for ease of recognition in the drawings.

FIG. 1 is a schematic diagram of a hybrid computing system including a digital computer coupled to an analog computer, in accordance with the present systems, devices, and methods.

FIG. 2 is a schematic diagram of a portion of an example superconducting quantum processor, in accordance with the present systems, devices, and methods.

FIGS. 3A, 3B, 3C, 3D, 3E, and 3F are sectional views of an example circuit at successive stages of fabrication, in accordance with the present systems, devices, and methods.

FIG. 4 is a flow chart of an example fabrication method for a multi-layer integrated circuit, in accordance with the present systems, devices, and methods.

FIGS. 5A, 5B, 5C, 5D, 5E, and 5F are sectional views of an example circuit at successive stages of fabrication, in accordance with the present systems, devices, and methods.

FIGS. 6A, 6B, and 6C are sectional views of an alternative example circuit at successive stages of fabrication, in accordance with the present systems, devices, and methods.

FIG. 7 is a flow chart of an example fabrication method for a multi-layer integrated circuit, in accordance with the present systems, devices, and methods.

FIGS. 8A, 8B, 8C, 8D, 8E, and 8F are sectional views of an example circuit at successive stages of fabrication, in accordance with the present systems, devices, and methods.

FIG. 9 is a flow chart of an example fabrication method for a multi-layer integrated circuit, in accordance with the present systems, devices, and methods.

FIG. 10 is a sectional view of an example multi-layer integrated circuit, in accordance with the present systems, devices, and methods.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” means that a particular feature, structure, or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

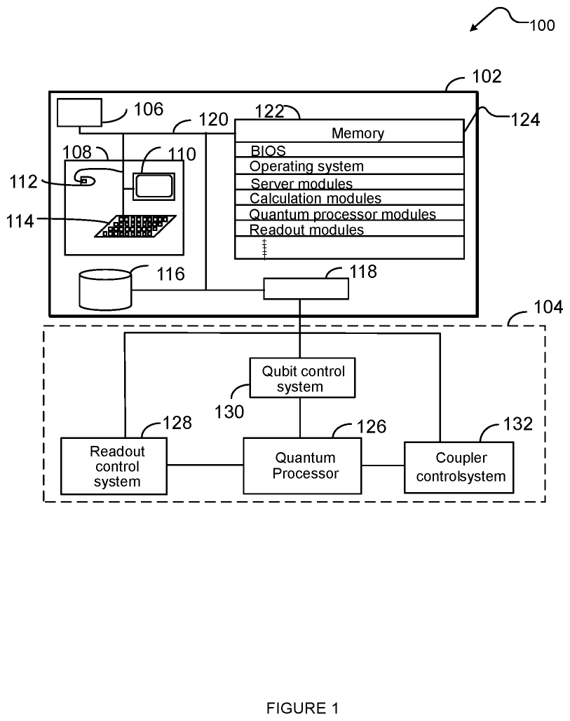

FIG. 1 illustrates a computing system 100 comprising a digital computer 102. The example digital computer 102 includes one or more digital processors 106 that may be used to perform classical digital processing tasks. Digital computer 102 may further include at least one system memory 122, and at least one system bus 120 that couples various system components, including system memory 122 to digital processor(s) 106. System memory 122 may store one or more sets of processor-executable instructions, which may be referred to as modules 124.

The digital processor(s) 106 may be any logic processing unit or circuitry (for example, integrated circuits), such as one or more central processing units (“CPUs”), graphics processing units (“GPUs”), digital signal processors (“DSPs”), application-specific integrated circuits (“ASICs”), programmable gate arrays (“FPGAs”), programmable logic controllers (“PLCs”), etc., and/or combinations of the same.

In some implementations, computing system 100 comprises an analog computer 104, which may include one or more quantum processors 126. Quantum processor 126 may include at least one superconducting integrated circuit. Digital computer 102 may communicate with analog computer 104 via, for instance, a controller 118. Certain computations may be performed by analog computer 104 at the instruction of digital computer 102, as described in greater detail herein.

Digital computer 102 may include a user input/output subsystem 108. In some implementations, the user input/output subsystem includes one or more user input/output components such as a display 110, mouse 112, and/or keyboard 114.

System bus 120 may employ any known bus structures or architectures, including a memory bus with a memory controller, a peripheral bus, and a local bus. System memory 122 may include non-volatile memory, such as read-only memory (“ROM”), static random-access memory (“SRAM”), Flash NAND; and volatile memory such as random-access memory (“RAM”).

Digital computer 102 may also include other non-transitory computer-or processor-readable storage media or non-volatile memory 116. Non-volatile memory 116 may take a variety of forms, including: a hard disk drive for reading from and writing to a hard disk (for example, a magnetic disk), an optical disk drive for reading from and writing to removable optical disks, and/or a solid state drive (SSD) for reading from and writing to solid state media (for example NAND-based Flash memory). Non-volatile memory 116 may communicate with digital processor(s) via system bus 120 and may include appropriate interfaces or controllers 118 coupled to system bus 120. Non-volatile memory 116 may serve as long-term storage for processor-or computer-readable instructions, data structures, or other data (sometimes called program modules or modules 124) for digital computer 102.

Although digital computer 102 has been described as employing hard disks, optical disks and/or solid-state storage media, those skilled in the relevant art will appreciate that other types of nontransitory and non-volatile computer-readable media may be employed. Those skilled in the relevant art will appreciate that some computer architectures employ nontransitory volatile memory and nontransitory non-volatile memory. For example, data in volatile memory may be cached to non-volatile memory or a solid-state disk that employs integrated circuits to provide non-volatile memory.

Various processor-or computer-readable and/or executable instructions, data structures, or other data may be stored in system memory 122. For example, system memory 122 may store instructions for communicating with remote clients and scheduling use of resources including resources on the digital computer 102 and analog computer 104. Also, for example, system memory 122 may store at least one of processor executable instructions or data that, when executed by at least one processor, causes the at least one processor to execute the various algorithms to execute instructions. In some implementations system memory 122 may store processor-or computer-readable calculation instructions and/or data to perform pre-processing, co-processing, and post-processing to analog computer 104. System memory 122 may store a set of analog computer interface instructions to interact with analog computer 104. For example, the system memory 122 may store processor-or computer-readable instructions, data structures, or other data.

Analog computer 104 may include at least one analog processor such as quantum processor 126. Analog computer 104 may be provided in an isolated environment, for example, in an isolated environment that shields the internal components of the quantum computer from heat, magnetic field, and other external noise. The isolated environment may include a refrigerator, for instance a dilution refrigerator, operable to cryogenically cool the analog processor, for example to temperature below approximately 1 K.

Analog computer 104 may include programmable devices such as qubits, couplers, and other devices (also referred to herein as controllable devices). Qubits may be read out via readout control system 128. Readout results may be sent to other computer-or processor-readable instructions of digital computer 102. Qubits may be controlled via a qubit control system 130. Qubit control system 130 may include on-chip Digital to Analog Converters (DACs) and analog lines that are operable to apply a bias to a target device. Couplers that couple qubits may be controlled via a coupler control system 132. Coupler control system 132 may include tuning components such as on-chip DACs and analog lines. Qubit control system 130 and coupler control system 132 may be used to implement a quantum annealing schedule as described herein on analog computer 104. Programmable components may be included in quantum processor 126 in the form of an integrated circuit. Qubits and couplers may be positioned in layers of the integrated circuit that comprise a first material. Other devices, such as readout control system 128, may be positioned in other layers of the integrated circuit that comprise a second material. In accordance with the present disclosure, a quantum processor, such as quantum processor 126, may be designed to perform quantum annealing and/or adiabatic quantum computation or may be designed to perform gate or circuit model quantum computation. Example implementations of quantum processors are described in U.S. Pat. No. 7,533,068 and U.S. Provisional Patent Application No. 63/356,663.

Quantum processors may perform two general types of quantum computation. The first, quantum annealing and/or adiabatic quantum computation, generally relies on the physical evolution of a quantum system. Gate, or circuit, model quantum computation relies on the use of quantum gate operations to perform computations with data. Surface code refers to a particular implementation of error-corrected gate or circuit quantum computation, wherein logical qubits are encoded into portions or patches of a square lattice of physical qubits using a two-dimensional low density parity check scheme. Other implementations of gate model quantum computation are known in the art.

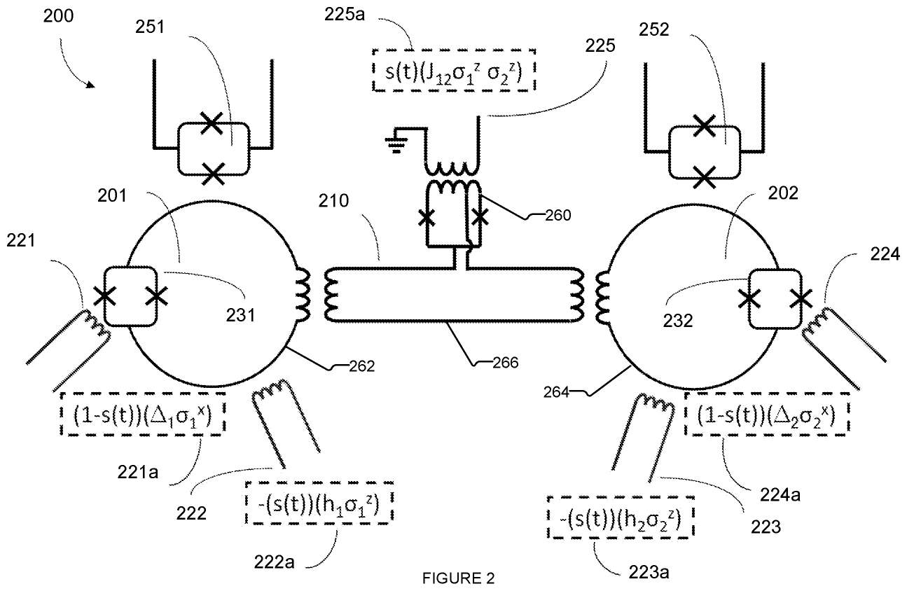

FIG. 2 is a schematic diagram of a portion of an example of a superconducting quantum processor 200, according to at least one implementation. The portion of superconducting quantum processor 200 shown in FIG. 2 includes two superconducting qubits 201 and 202. Also shown is a coupler 210 providing tunable coupling via between qubits 201 and 202 (i.e., providing 2-local interaction). While the portion of quantum processor 200 shown in FIG. 2 includes only two qubits 201, 202 and one coupler 210, those of skill in the art will appreciate that quantum processor 200 may include any number of qubits and any number of couplers coupling information between the qubits.

Quantum processor 200 includes a plurality of interfaces 221, 222, 223, 224, 225 that are used control the state of quantum processor 200. Each of interfaces 221-225 may be realized by a respective inductive coupling structure, as illustrated, as part of a programming subsystem and/or an evolution subsystem. Alternatively, or in addition, interfaces 221-225 may be realized by a galvanic coupling structure. In some implementations, one or more of interfaces 221-225 may be driven by one or more DACs. Such a programming subsystem and/or evolution subsystem may be separate from quantum processor 200, or may be included locally (i.e., on-chip with quantum processor 200).

In the operation of quantum processor 200, interfaces 221 and 224 may each be used to couple a flux signal into a respective compound Josephson junction 231 and 232 of qubits 201 and 202, thereby realizing a tunable tunneling term (the ≢ᵢ term) in the system Hamiltonian. This coupling provides the off-diagonal σ^{x} terms of the Hamiltonian and these flux signals are examples of “delocalization signals”. Examples of Hamiltonians (and their terms) used in quantum computing are described in greater detail in, for example, U.S. Pat. No. 9,424,526.

Similarly, interfaces 222 and 223 may each be used to apply a flux signal into a respective qubit loop of qubits 201 and 202, thereby realizing the hᵢ terms (dimensionless local fields for the qubits) in the system Hamiltonian. This coupling provides the diagonal σ^{z} terms in the system Hamiltonian. Furthermore, interface 225 may be used to couple a flux signal into coupler 210, thereby realizing the Jᵢⱼ term(s) (dimensionless local fields for the couplers) in the system Hamiltonian. This coupling provides the diagonal σᵢ^{z}σⱼ^{z} terms in the system Hamiltonian.

In FIG. 2, the contribution of each of interfaces 221-225 to the system Hamiltonian is indicated in broken line boxes 221a, 222a, 223a, 224a, 225a, respectively. As shown, in the example of FIG. 2, the broken line boxes 221a-225a are elements of time-varying Hamiltonians for quantum annealing and/or adiabatic quantum computing.

While quantum processor 200 is an example of a quantum annealing processor, it will be understood that the methods described herein may also be applied to other types of quantum processors, such as gate or circuit model quantum processors. Herein, the term “quantum processor” is used to generally describe a collection of physical qubits (e.g., qubits 201 and 202) and qubit couplers (e.g., coupler 210). Physical qubits 201 and 202 and coupler 210 are referred to as the “controllable devices” of quantum processor 200 and their corresponding parameters (e.g., the qubit hᵢ values and the coupler Jᵢⱼ values) are referred to as the “controllable parameters” of the quantum processor. In the context of a quantum processor, the term “programming subsystem” is used to generally describe the interfaces (e.g., “programming interfaces” 222, 223, and 225) used to apply the controllable parameters to the controllable devices of quantum processor 200 and other associated control circuitry and/or instructions. In some implementations, programming interfaces 222, 223, and 225 may include DACs. DACs may also be considered “programmable devices” that are used to control controllable devices such as qubits, couplers, and parameter tuning devices.

As previously described, the programming interfaces of the programming subsystem may communicate with other subsystems which may be separate from the quantum processor or may be included locally on the processor chip. The programming subsystem may receive programming instructions in a machine language of the quantum processor and execute the programming instructions to program the programmable and controllable devices in accordance with the programming instructions. Similarly, in the context of a quantum processor, the term “evolution subsystem” generally includes the interfaces (e.g., “evolution interfaces” 221 and 224) used to evolve devices such as the qubits of quantum processor 200 and other associated control circuitry and/or instructions in implementations where quantum processor 200 performs quantum annealing and/or adiabatic quantum computing. For example, the evolution subsystem may include annealing signal lines and their corresponding interfaces 221, 224 to communicate with qubits 201, 202. Evolution may refer to performing quantum annealing, or to other types of quantum computations.

Quantum processor 200 also includes readout devices 251 and 252, where readout device 251 is associated with qubit 201 and readout device 252 is associated with qubit 202. In the example implementation shown in FIG. 2, each of readout devices 251 and 252 includes a direct current superconducting quantum interference device (DC-SQUID) inductively coupled to the corresponding qubit. In the context of quantum processor 200, the term “readout subsystem” is used to generally describe the readout devices 251, 252 used to read out the final states of the qubits (e.g., qubits 201 and 202) in quantum processor 200 to produce a bit string. The readout subsystem may also include other elements, such as routing circuitry (e.g., latching elements, a shift register, or a multiplexer circuit) and/or may be arranged in alternative configurations (e.g., an XY-addressable array, an XYZ-addressable array, etc.), any of which may comprise DACs. Qubit readout may also be performed using alternative circuits, such as that described in U.S. Pat. No. 8,854,074.

While FIG. 2 illustrates only two physical qubits 201, 202, one coupler 210, and two readout devices 251, 252, a quantum processor (e.g., processor 200) may employ any number of qubits, couplers, and/or readout devices, including a larger number (e.g., hundreds, thousands or more) of qubits, couplers and/or readout devices. The application of the teachings herein to processors with a different (e.g., larger) number of computational components should be readily apparent to those of ordinary skill in the art.

Examples of superconducting qubits include superconducting flux qubits, superconducting charge qubits, and the like. In a superconducting flux qubit, the Josephson energy dominates or is equal to the charging energy. In a charge qubit this is reversed. Examples of flux qubits that may be used include radio frequency superconducting quantum interference devices (rf-SQUIDs), which include a superconducting loop interrupted by one Josephson junction, persistent current qubits, which include a superconducting loop interrupted by three Josephson junctions, and the like. One example of a superconducting charge qubit is the transmon qubit.

A qubit (e.g., 201, 202) is an example of a noise-susceptible device in a quantum processor. A coupler (e.g., 210) is another example. In the present specification, the phrase “noise-susceptible superconducting device” or “device having high susceptibility to noise” is used to describe a superconducting device that is susceptible to noise and for which a noise-free operating environment is highly desirable for performance of a superconducting integrated circuit such as a quantum processor. Poor performance of a noise-susceptible device may result in the quantum processor producing an inaccurate or suboptimal solution to a problem, for example, an inaccurate or suboptimal result of quantum annealing or a gate model computation. Note that the phrases “noise-susceptible” and “susceptible to noise” do not necessarily suggest that the device itself is physically more or less sensitive to noise compared to other devices that are not described as noise-susceptible. Instead, “noise-susceptible” is used to refer to the sensitivity of processor performance to noise within a given device. The sensitivity of the processor performance to noise is higher in noise-susceptible devices than in devices that are described as less susceptible to noise or as “devices having low susceptibility to noise”. Sources of noise in a quantum processor may, for example, include but are not limited to: flux noise, charge noise, magnetic fields, and high frequency photons.

Fabrication techniques may beneficially be performed to provide circuits having lower inherent noise. Superconducting materials have noise properties that are inherent to the material, motivating the exploration of new superconducting materials for quantum processors in the face of fabrication challenges. In a multi-layered integrated circuit (either a semiconducting circuit or a superconducting circuit), successive layers of superconductive wiring and/or traces are typically separated from one another by inner layer dielectrics (“ILDs”). As used herein, “wires” and “wiring” within a multi-layered integrated circuit includes traces of electrically conductive materials. ILDs provide structural support for the circuit while electrically insulating adjacent conductive layers. In addition to the noise properties of the metals, the interlayer dielectric materials that are arranged between metal layers in a fabrication stack have inherent noise properties. One source of noise from interlayer dielectrics is lattice defects that can cause the material to behave as a two level system. In some implementations, interlayer dielectrics that are deposited at higher temperatures may have fewer two level systems, resulting in less noise. Therefore, it may be beneficial to use materials that can withstand these higher temperatures without degradation in the fabrication stack.

Material choice for superconducting fabrication stacks must consider properties of the materials applicable to its use in fabrication, such as the preferred or optimal deposition temperature, and the techniques available to pattern that material, as well as properties of the materials during operation of the resultant superconducting circuit, such as the noise characteristics. The use of alpha phase tantalum (α-tantalum) in superconducting quantum processors may beneficially allow for use of higher temperature dielectrics and lower noise. In addition, deposition of α-tantalum at or around an ambient temperature (i.e., room temperature, typically around 20° C.) may beneficially increase compatibility with other materials that may be impacted or damaged by higher temperature depositions, for example, in hybrid metal stacks. This benefit may also apply to higher temperatures that are still well below a temperature that may damage surrounding materials, such temperatures that are less than 100° C., or less than 250° C. The critical temperature of α-tantalum, at which and below it becomes superconducting, is approximately 4.5K, which may also be advantageous to the operation of the quantum computer. In some implementations, a superconducting material having a critical temperature above 1 K may beneficially result in a processor that is more robust to temperature fluctuations, and may also provide better shielding of processor components. Growth of α-tantalum is discussed generally in Place et al., New material platform for superconducting transmon qubits with coherence times exceeding 0.3 milliseconds, arXiv: 2003.00024v1, Feb. 28, 2020. While some techniques for growth of α-tantalum may require high temperatures for deposition, which may negatively impact other characteristics of the processor, it has been found that α-tantalum may beneficially be deposited at or near ambient temperature using an aluminum seed layer. A seed layer refers generally to a thin layer of material that is deposited as a precursor layer to enhance or enable the deposition of a primary material.

Superconducting devices such as qubits and couplers, such as the example devices 201, 202, and 210 of FIG. 2, have Josephson junction structures such as structures 231, 232, and 260 of FIG. 2, and body wiring (e.g., electrically conductive traces), such as 262, 264, and 266 of FIG. 2. In some implementations it can be beneficial to form the body wiring of such devices in one region of a fabrication stack and the Josephson junction structures in another region of a fabrication stack having different material properties. For example, in some implementations, noise susceptible devices such as qubits and couplers may beneficially be formed in layers of α-tantalum. In some implementations, a multi-layer fabrication stack may include the body wiring of noise susceptible devices formed in layers of α-tantalum and Josephson junctions of the noise susceptible devices formed of an alternative superconducting material. In other implementations, a material with desirable operational properties, such as lower noise, may have less desirable properties for use in fabrication, such as being soft and easily damageable by polishing acts. In some implementations, a layer of α-tantalum may beneficially be used as a polish stop over a layer of a different superconducting material, such as aluminum.

Unless the specific context requires otherwise, throughout this specification the terms “deposit”, “deposited”, “deposition”, and the like are generally used to encompass any method of material deposition, including but not limited to: physical vapor deposition (PVD), chemical vapor deposition (CVD), plasma-enhanced PVD, plasma-enhanced CVD, and atomic layer deposition (ALD). “Forming” may include: electron beam lithography, sputtering, electron beam evaporation, thermal evaporation, vapor deposition, vacuum evaporation, electron beam masking, photolithography, liftoff masking, etching, or other cutting and patterning methods. “Patterning” may include: masking and etching, reactive ion etch (RIE), and other additive or subtractive patterning methods known in the art. “Polishing” and “planarizing” may refer to techniques such as chemical-mechanical polishing (CMP) and other polishing techniques known in the art. The terms “polishing” and “planarizing” and variations thereof (e.g., polished, planarized) are used interchangeably throughout this document.

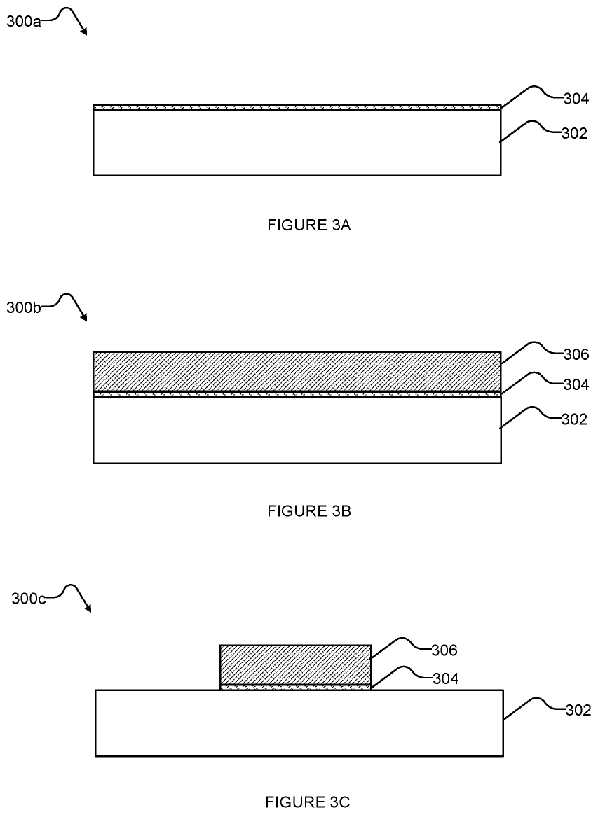

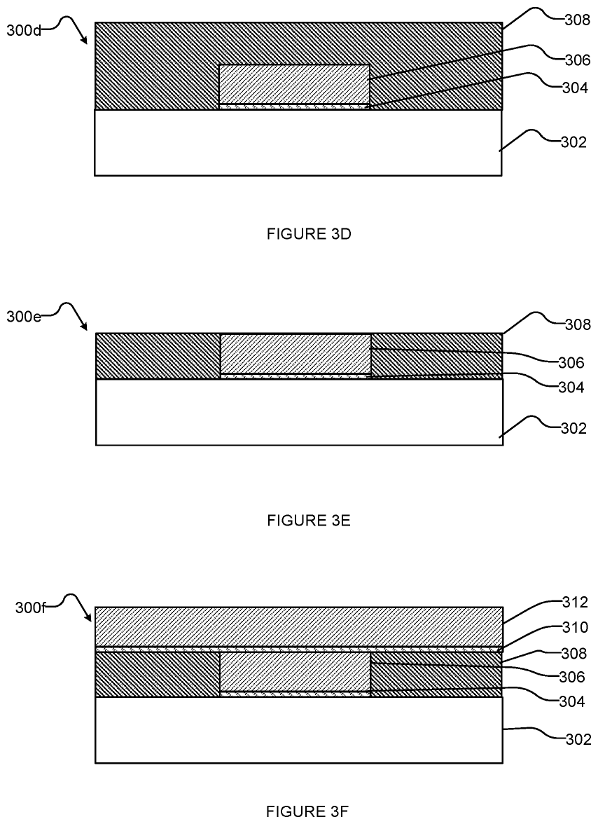

FIGS. 3A, 3B, 3C, 3D, and 3E are sectional views of an example circuit at successive stages of fabrication, in accordance with the present systems, devices, and methods.

FIG. 3A is a sectional view of a superconducting integrated circuit 300a with a substrate 302 and an aluminum seed layer 304 overlying substrate 302. In some implementations, substrate 302 may be formed of: silicon, sapphire, quartz, silicon dioxide, or any similar suitable material. In some implementations, aluminum seed layer 304 may have a thickness greater than 5 nm, such as a thickness in a range of 5 nm to 300 nm. In some implementations aluminum seed layer 304 may have a thickness in a range of 10 nm to 50 nm. In some implementations, aluminum seed layer 304 may beneficially be sufficiently thin to reduce the contribution of the seed layer material to the noise of the circuit while also being sufficiently thick to provide a crystalline structure for deposition. In some implementations, the temperature may be controlled during deposition of aluminum seed layer 304 to control the aluminum grain size to provide a surface that is beneficial for the growth of α-tantalum. For example, in some implementations, a beneficial surface is one that results in a layer of α-tantalum having a critical temperature of equal to or greater than 4.3K, or one having only a minority fraction or trace amounts of β-tantalum.

A “layer” as used herein refers to a material having a thickness, where at least a portion of the material is in contact with at least a portion of an additional surface. Materials of one layer may be patterned and other materials may fill in the gaps of the patterned areas. Consequently, while referred to as layers, two or more denominated layers can reside on a same or common level or plane spaced over the substrate.

In the description of superconducting circuits herein, the terms “overlie” and “overlying” can describe a position of a layer and/or component in relation to the substrate of the superconducting circuit in the plane of the drawing pages. While this assumes a particular orientation of substrate for ease of discussion, this is not intended to be limiting. Thus, the orientation of a superconducting circuit as illustrated in any one of the drawings, can be flipped upside down, for example.

As used throughout, the terms “overlie” and “overlying” encompass arrangements including “directly overlying”, which refers to a layer being formed directly on the noted layer without an intervening layer and “indirectly overlying”, which refers to a layer being formed over at least a portion of the noted layer, with at least one intervening layer between the substrate and the referenced layer.

FIG. 3B is a sectional view of a superconducting integrated circuit 300b with substrate 302 and aluminum seed layer 304 as in FIG. 3A, with an α-tantalum layer 306 directly overlying aluminum seed layer 304. It has been found that an aluminum seed layer beneficially provides a compatible crystalline structure to produce α-tantalum during deposition, as opposed to another form of tantalum such as β-tantalum. As discussed above, the temperature may be controlled during deposition of aluminum seed layer 304 to control the aluminum grain size to provide a surface that is beneficial for the growth of α-tantalum. In some implementations, deposition on aluminum seed layer 304 allows for α-tantalum to be deposited at or near ambient temperature and/or without supplemental heating. In other implementations, deposition on aluminum seed layer 304 allows for α-tantalum to be deposited at a temperature that is sufficiently low not to damage materials in the fabrication stack, such as below 100° C. or below 250° C.

FIG. 3C is a sectional view of a superconducting integrated circuit 300c with substrate 302, aluminum seed layer 304, and α-tantalum layer 306 directly overlying aluminum seed layer 304 as in FIG. 3B, with α-tantalum layer 306 and aluminum seed layer 304 patterned. In some implementations, α-tantalum layer 306 and aluminum seed layer 304 may be patterned to form the body wiring of one or more qubits, such as body loops 262 and 264 of qubits 201 and 202, or one or more couplers, such as body loop 266 of coupler 210, as part of a quantum processor.

FIG. 3D is a sectional view of a superconducting integrated circuit 300d with substrate 302, aluminum seed layer 304, and α-tantalum layer 306 directly overlying aluminum seed layer 304 as in FIG. 3C, and a dielectric layer 308 overlying α-tantalum layer 306. In some implementations, dielectric layer 308 may be SiOₓ, SiNₓ, α-Si (amorphous silicon), or any other suitable dielectric material as is known in the art.

FIG. 3E is a sectional view of a superconducting integrated circuit 300e with substrate 302, aluminum seed layer 304, α-tantalum layer 306 directly overlying aluminum seed layer 304, and dielectric layer 308 overlying α-tantalum layer 306 as in FIG. 3D that has been planarized (e.g., CMP) to be level or flush with an upper surface of α-tantalum layer 306, thereby exposing at least a portion of the upper surface of α-tantalum layer 306.

FIG. 3F is a sectional view of a superconducting integrated circuit 300f with substrate 302, aluminum seed layer 304, α-tantalum layer 306 directly overlying aluminum seed layer 304, and dielectric layer 308 as in FIG. 3E, as well as an additional aluminum seed layer 310 overlying dielectric layer 308 and an additional α-tantalum layer 312 directly overlying additional aluminum seed layer 310.

It will be understood that the size and shape of components in FIGS. 3A through 3F are examples, and that in other implementations the size and shape of patterned components can be varied in accordance with the type of circuit or device being formed. For example, additional aluminum seed layer 310 and additional-tantalum layer 312 may also be patterned, and additional layers of dielectric and metal may be added. Aluminum seed layer 304 and α-tantalum layer 306 may be in direct contact with additional aluminum seed layer 310 and additional α-tantalum layer 312, or these components may be separated by one or more dielectric layers. In some implementations aluminum seed layer 304 and α-tantalum layer 306 may form a plurality of quantum devices or portions of quantum devices, such as a plurality of qubit body wiring loops, and additional aluminum seed layer 310 and additional α-tantalum layer 312 may form connections with one or more of the plurality of quantum devices.

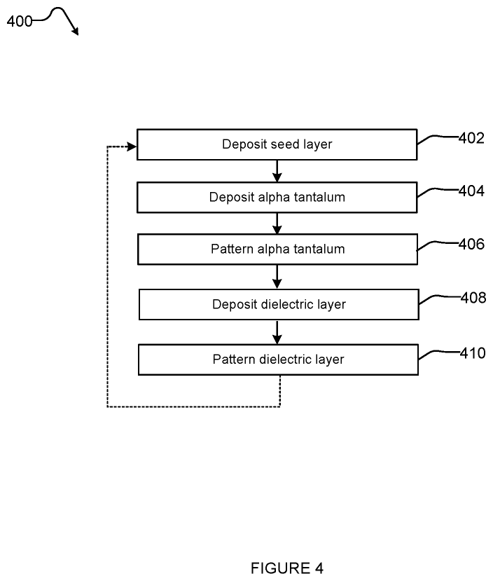

FIG. 4 is a flow chart illustrating an example fabrication method 400 for a multi-layer integrated circuit, such as, for example, superconducting integrated circuit 300e of FIG. 3E or superconducting integrated circuit 300f of FIG. 3F following fabrication illustrated at successive stages in FIGS. 3A through 3F, in accordance with the present systems, devices, and methods. Method 400 includes acts 402-410, although in other implementations certain acts may be omitted, additional acts may be added, and/or the acts may be performed in different orders.

Method 400 may be performed by, for example, integrated circuit fabrication equipment in response to an initiation of a fabrication process.

At 402, an aluminum seed layer is deposited, as shown in the example implementation of FIG. 3A in which aluminum seed layer 304 overlies substrate 302. The aluminum seed layer may be deposited to have a thickness greater than 5 nm, such as a thickness in a range of 5 nm to 300 nm, and in some implementations, may be deposited to have a thickness in a range of 10 nm to 50 nm. As used herein, “depositing” may include both an initial formation operation in which a uniform layer of material is deposited onto an underlying surface, and subsequent patterning operations performed on the material to form wiring (e.g., traces), devices, and other structures. Depositing may include a variety of deposition techniques, such as electron beam lithography, vapor deposition, vacuum evaporation, and other cutting and patterning methods. It will be understood that similar deposition techniques may be used in the other depositing acts described herein. In some implementations, the temperature may be controlled during deposition of the aluminum seed layer to control the aluminum grain size to provide a surface that is beneficial for the growth of α-tantalum.

At 404, a layer of α-tantalum is deposited directly onto at least a portion of the aluminum seed layer, as shown in the example implementation of FIG. 3B in which α-tantalum layer 306 directly overlies aluminum seed layer 304.

At 406, the layer of α-tantalum is patterned, as shown in the example implementation of FIG. 3C in which α-tantalum layer 306 and aluminum seed layer 304 have been patterned.

At 408, a dielectric layer is deposited overlying the layer of α-tantalum, as shown in the example implementation of FIG. 3D in which dielectric layer 308 overlies α-tantalum layer 306. In some implementations, the dielectric layer may SiOₓ, SiNₓ, and a-Si, or any other suitable dielectric material as is known in the art. In some implementations, the dielectric layer may be deposited at a temperature below the melting point of aluminum. For example, in some implementations, the dielectric layer may be deposited at a temperature that is less than 650° C. In some implementations, the dielectric layer may be deposited at a temperature that is less than 250° C., or at a temperature that is less than 100° C., or a temperature that is at or near ambient temperature or room temperature.

At 410, the dielectric layer is patterned, as shown in the example implementation of FIG. 3E. While in the example implementation of FIG. 3E dielectric layer 308 is patterned by polishing or planarizing to the level of an upper surface of α-tantalum layer 306, in other implementations the dielectric layer may be patterned according to other methods known in the art, such as masking and etching, and in some implementations dielectric layer 308 may overlie all or part of α-tantalum layer 306.

After 410, method 400 may end, or method 400 may optionally be repeated iteratively to form a multi-layer stack, as shown in the example implementation of FIG. 3F. For example, method 400 may include depositing additional aluminum seed layers, α-tantalum layers, and dielectric layers and patterning the respective layers to form all or a portion of a quantum processor, such as quantum processor 126 of FIG. 1 or the quantum processor 200 of FIG. 2, which can include a plurality of qubits and a plurality of couplers, such as qubits 201 and 202 and coupler 210 of FIG. 2.

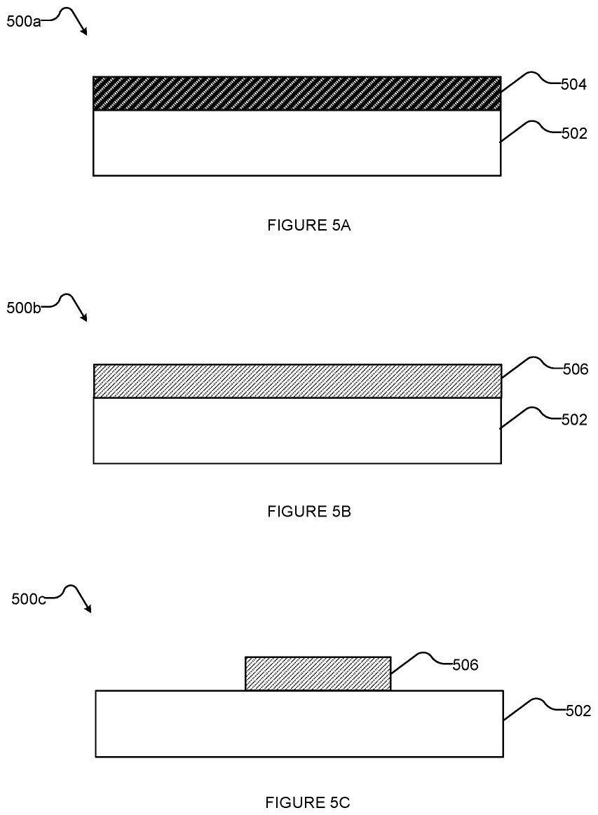

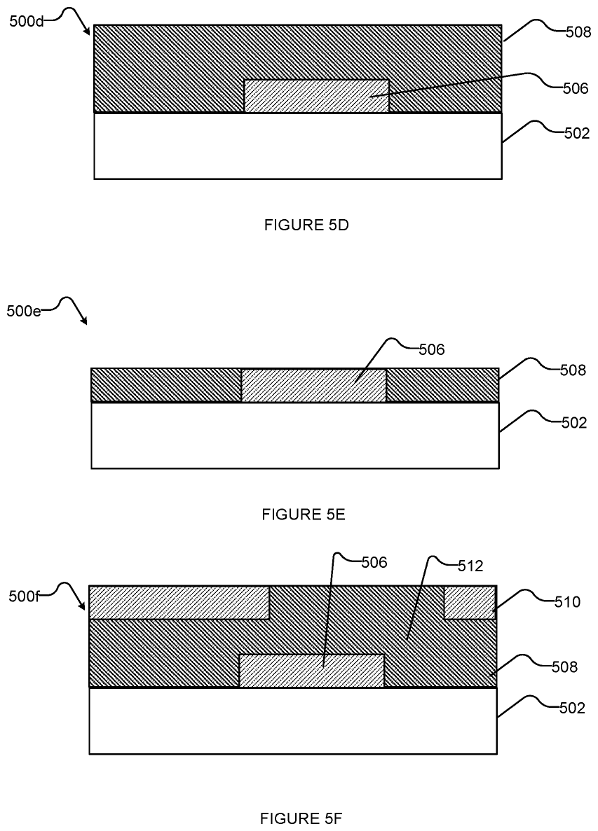

FIGS. 5A, 5B, 5C, 5D, 5E, and 5F are sectional views of an example circuit at successive stages of fabrication, in accordance with the present systems, devices, and methods.

FIG. 5A is a sectional view of an example circuit 500a having a substrate 502 and a first layer of β-tantalum 504 deposited to overlie substrate 502. In some implementations, substrate 502 may be formed of silicon, sapphire, quartz, silicon dioxide, or any similar suitable material.

FIG. 5B is a sectional view of an example circuit 500b that is similar to example circuit 500a, where first layer of β-tantalum 504 has been heated to form layer of α-tantalum 506. As discussed herein, heating β-tantalum to form α-tantalum refers to converting an effective majority to α-tantalum, such that measurable material properties of the metal layer are consistent with those of α-tantalum. It will be understood that in some implementations a minority fraction or trace amounts of β-tantalum may be present. For example, the critical temperature at which β-tantalum becomes superconducting is around 0.6 to 1.0 K, while the critical temperature of α-tantalum is approximately 4.4K. The layer of tantalum may, for example, be considered to have formed α-tantalum when the measured critical temperature is at or higher than 4.3K. In other examples, material properties such as resistivity may be used.

FIG. 5C is a sectional view of an example circuit 500c that is similar to example circuit 500b, in which layer of α-tantalum 506 has been patterned.

FIG. 5D is a sectional view of an example circuit 500d that is similar to example circuit 500c, and that also includes a dielectric layer 508 that has been deposited to overlie layer of α-tantalum 506. In some implementations, dielectric layer 508 may be SiOₓ, SiNₓ, a-Si, or any other suitable dielectric material as is known in the art.

FIG. 5E is a sectional view of an example circuit 500e that is similar to example circuit 500d, in which dielectric layer 508 has been patterned to be level or flush with an upper surface of layer of α-tantalum 506, thereby exposing at least a portion of the upper surface of layer of α-tantalum 506.

FIG. 5F is a sectional view of an example circuit 500f that is similar to example circuit 500e, and also includes a second layer of α-tantalum 510 that has been formed (i.e., by heating of a second layer of deposited β-tantalum for sufficient time that measurable material properties of the metal layer are consistent with those of α-tantalum) to overlie dielectric layer 508 and has been subsequently patterned, and a second layer of dielectric 512 that has been formed to overlie second layer of α-tantalum 510 and has been subsequently patterned. In some implementations, second layer of dielectric 512 may be SiOₓ, SiNₓ, a-Si, or any other suitable dielectric material as is known in the art.

In some implementations, the heating that occurs to transition between the example circuits 500a and 500b may be performed as a distinct act after deposition of first layer of β-tantalum 504. In other implementations, the substrate 502 may be held on a heated chuck and/or within a heated chamber such that the β-tantalum is heated to α-tantalum during or concurrently (e.g., simultaneous) with the deposition. In other implementations, the heating may be performed by the deposition of a hot dielectric that raises the temperature of the underlying tantalum, and/or by deposition of the dielectric in a hot environment.

It will be understood that the size and shape of components in FIGS. 5A through 5F are examples, and that in other implementations the size and shape of patterned components can be varied in accordance with the type of circuit or device being formed. For example, in some implementations electrical connections may be formed between first layer of α-tantalum 506 and second layer of α-tantalum 510. In some implementations additional layers of dielectric and α-tantalum may be formed.

In some implementations, circuits such as example circuit 500f may form part of a multi-layer superconducting integrated circuit within a quantum processor, such as quantum processor 126 of FIG. 1. For example, such a circuit may include a substrate, such as substrate 502, a first layer of α-tantalum layer overlying the substrate, such as first layer of α-tantalum 506, a dielectric layer overlying the first α-tantalum layer, such as second layer of dielectric 512, and a second α-tantalum layer indirectly overlying the first α-tantalum layer, such as second layer of α-tantalum 510. At least one of the first α-tantalum layer and the second α-tantalum can form body wiring of one or more qubits within the quantum processor, such as qubits 201 and 202 of FIG. 2. In some implementations, at least one of the first α-tantalum layer and the second α-tantalum may also form body wiring of one or more couplers, such as coupler 210 of FIG. 2.

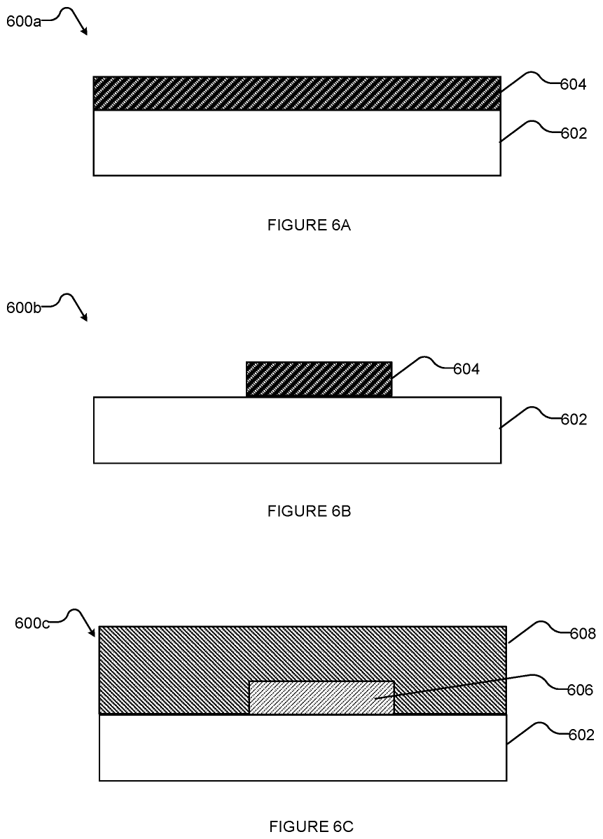

FIGS. 6A, 6B, and 6C are sectional views of an alternative example circuit at successive stages of fabrication, in accordance with the present systems, devices, and methods.

FIG. 6A is a sectional view of an example circuit 600a having a substrate 602 and a first layer of β-tantalum 604 deposited to overlie substrate 602. As shown, first layer of β-tantalum 604 directly overlies substrate 602, however, it will be understood that in other implementations, first layer of β-tantalum 604 may be formed with intervening layers between first layer of β-tantalum 604 and substrate 602. In some implementations, substrate 602 may be formed of silicon, sapphire, quartz, silicon dioxide, or any similar suitable material.

FIG. 6B is a sectional view of an example circuit 600b that is similar to example circuit 600a, and in which first layer of β-tantalum 604 has been patterned.

FIG. 6C is a sectional view of an example circuit 600c that is similar to example circuit 600b, and also includes a dielectric layer 608 has been deposited to overlie the layer that was previously first layer of β-tantalum 604, which has been heated by or concurrently (e.g., simultaneously) with the deposition of dielectric layer 608 to transition first layer of β-tantalum 604 to layer of α-tantalum 606. In some implementations, dielectric layer 608 may be SiOₓ, SiNₓ, a-Si, or any other suitable dielectric material as is known in the art.

It will be understood that the size and shape of components in FIGS. 6A through 6C are examples, and that in other implementations the size and shape of patterned components can be varied in accordance with the type of circuit or device being formed. For example, in some implementations additional layers of α-tantalum and dielectric may be formed.

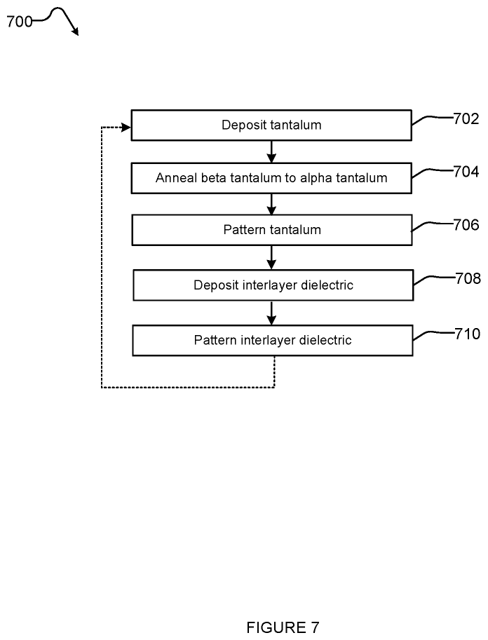

FIG. 7 is a flow chart of an example method 700 of fabricating a multi-layer integrated circuit, such as the example integrated circuits following fabrication illustrated at successive stages in FIGS. 5A through 5F and the example integrated circuits following fabrication illustrated at successive stages in FIGS. 6A through 6C, in accordance with the present systems, devices, and methods. Method 700 includes acts 702-710, although in other implementations certain acts may be omitted, additional acts may be added, and/or the acts may be performed in different orders. Method 700 may be performed by, for example, integrated circuit fabrication equipment in response to an initiation of a fabrication process.

At 702, a layer of tantalum is deposited. In some implementations, the layer of tantalum is first layer of β-tantalum 504 deposited to overlie substrate 502 in FIG. 5A. In other implementations, layer of tantalum is first layer of β-tantalum 604 deposited to overlie substrate 602 in FIG. 6A.

At 704, the β-tantalum is heated to form α-tantalum, as shown in the example implementation of FIG. 5B, in which first layer of β-tantalum 504 has been transformed to layer of α-tantalum 506, and the example implementation of FIG. 6C, in which first layer of β-tantalum 604 has been transformed to layer of α-tantalum 606. As discussed above, this act may occur concurrently (e.g., simultaneously) with either the deposition of the layer of tantalum or the deposition of the layer of dielectric, or may be a distinct act separate from deposition. In some implementations, heating the β-tantalum to form α-tantalum may involve depositing the layer of tantalum onto a surface having a temperature greater than 500° C. such that the β-tantalum becomes α-tantalum as the layer of tantalum is deposited. In other implementations, heating the β-tantalum to form α-tantalum may involve depositing the dielectric layer at a temperature greater than 500° C. such that the β-tantalum becomes α-tantalum in response to heating from the dielectric layer. In further implementations, heating the β-tantalum to form α-tantalum may involve heating the β-tantalum to a temperature greater than 500° C. for sufficient time that the β-tantalum is transformed into α-tantalum after depositing the layer of tantalum and prior to depositing the dielectric layer.

In some implementations, it may be beneficial to confirm that the β-tantalum has formed α-tantalum prior to proceeding with further acts. As discussed above, heating β-tantalum to form α-tantalum refers to converting an effective majority to α-tantalum, such that measurable material properties of the metal layer are consistent with those of α-tantalum. It will be understood that in some implementations a minority fraction or trace amounts of β-tantalum may be present. In some implementations, confirming that the β-tantalum has formed α-tantalum may involve measuring the critical temperature of the tantalum layer. The layer of tantalum may, for example, be considered to have formed α-tantalum when the measured critical temperature is at or higher than 4.3K. In other examples, one or more resistance measurements of the layer of tantalum may be performed prior to proceeding with further acts to confirm that the layer of tantalum is a layer of α-tantalum.

At 706, the layer of tantalum is patterned. In the example implementation of FIG. 5C, layer of α-tantalum 506 is shown to be patterned. In the example implementation of FIG. 6B, first layer of β-tantalum 604 is shown to be patterned. Here, act 706 is performed before act 704, at which point layer of α-tantalum 606 is formed by heating patterned first layer of β-tantalum 604.

At 708, a dielectric layer is deposited to overlie the layer of tantalum, as shown in the example implementation of FIG. 5D, in which dielectric layer 508 overlies layer of α-tantalum 506, and the example implementation of FIG. 6C, in which dielectric layer 608 overlies layer of α-tantalum 606. In some implementations the dielectric layer may be deposited at a temperature in the range of 700° C. and 800° C., and as discussed above, in some implementations the deposition of the dielectric layer may heat a layer of β-tantalum to transition to α-tantalum. In some implementations, the dielectric layer may be one of SiOₓ, SiNₓ, and a-Si. In particular, these dielectrics (SiOₓ, SiNₓ, and a-Si) may be deposited at a temperature in the range of 700° C. and 800° C.

At 710, the dielectric layer is patterned, as shown in the example implementation of FIG. 5E.

After 710, method 700 may end, or method 700 may optionally be repeated iteratively to form a multi-layer stack, as shown in the example implementation of FIG. 5F. For example, method 700 may include depositing additional layers of tantalum made up of β-tantalum, additional dielectric layers, such as second layer of dielectric 512, and may include additional heating acts to transform the β-tantalum to α-tantalum, such as to form second layer of α-tantalum 510. Method 700 may also include patterning the respective layers to form a quantum processor comprising a plurality of qubits and a plurality of couplers, such as qubits 201 and 202 and coupler 210 of FIG. 2.

In some implementations, fabrication processes for multi-layer fabrication stacks include polishing or planarizing, in which a dielectric layer is polished or planarized back to the surface of a metal layer. In some implementations, such as where the metal layer may be damaged by the polish or where the metal layer is not sufficiently hard to stop the polish, a polish stop layer may be included to directly overlie the metal wiring layer. The polish stop layer may be a relatively thin layer of a different material, such as a different superconducting material.

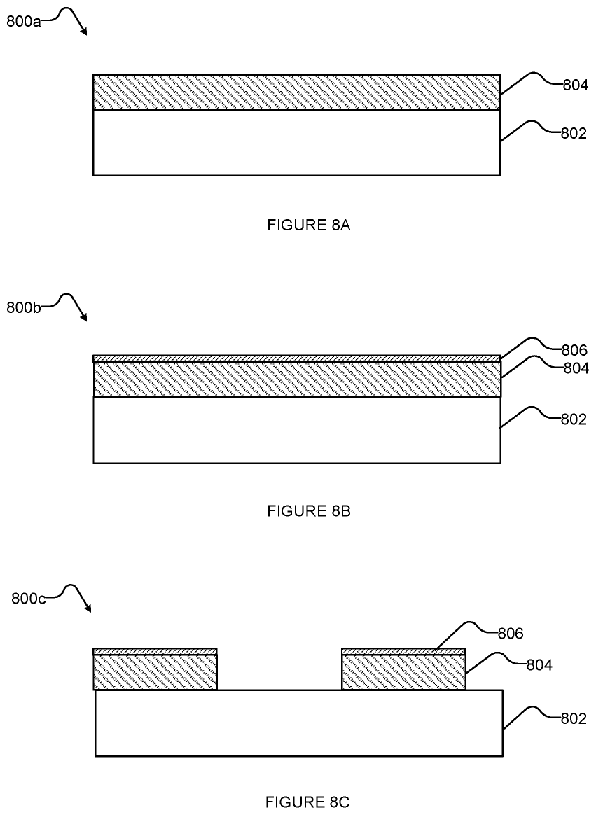

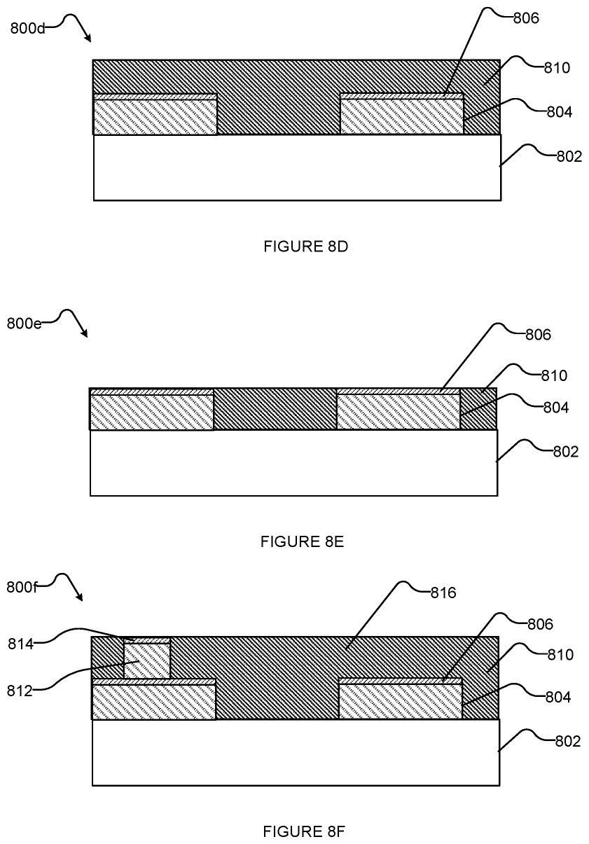

FIGS. 8A, 8B, 8C, 8D, and 8E are sectional views of an example circuit at successive stages of fabrication, in accordance with the present systems, devices, and methods.

FIG. 8A is a sectional view of an example circuit 800a having a substrate 802 and a first layer of aluminum 804 overlying substrate 802. In some implementations, substrate 802 may be formed of silicon, sapphire, quartz, silicon dioxide, or any similar suitable material.

FIG. 8B is a sectional view of an example circuit 800b that is similar to example circuit 800a, and also including a layer of α-tantalum 806 that has been deposited to directly overlie layer of aluminum 804. Layer of α-tantalum 806 can, in some example implementations, be a polish stop layer.

FIG. 8C is a sectional view of an example circuit 800c that is similar to example circuit 800b, in which layer of aluminum 804 and layer of α-tantalum 806 have been patterned.

FIG. 8D is a sectional view of an example circuit 800d that is similar to example circuit 800c, also including a dielectric layer 810 that has been deposited to overlie layer of aluminum 804 and layer of α-tantalum 806. In some implementations, dielectric layer 810 may be SiOₓ, SiNₓ, a-Si, or any other suitable dielectric material as is known in the art.

FIG. 8E is a sectional view of an example circuit 800e that is similar to example circuit 800d, in which dielectric layer 810 has been polished back to be level or flush with an upper surface of layer of α-tantalum 806, thereby exposing at least a portion of the upper surface of layer of α-tantalum 806. Layer of α-tantalum 806 can, in some implementation, act as a polish stop layer to protect layer of aluminum 804 from damage and ensure the polish ends at the desired height.

FIG. 8F is a sectional view of an example circuit 800f that is similar to example circuit 800e, which also includes: a second layer of aluminum 812 and a second layer of α-tantalum 814 that have been formed to overlie at least a portion of layer of α-tantalum 806 and have been subsequently patterned, and a second layer of dielectric 816 has been deposited and polished back to an upper surface of second layer of α-tantalum 814.

It will be understood that the size and shape of components in FIGS. 8A through 8F are examples, and that in other implementations the size and shape of patterned components can be varied in accordance with the type of circuit or device being formed. For example, aluminum layer 804 and α-tantalum layer 806 may be patterned differently, dielectric layer 810 may space α-tantalum layer 806 from aluminum layer 812, and additional layers of dielectric and metal may be added. In some implementations the aluminum and α-tantalum layers may collectively form a plurality of quantum devices or portions of quantum devices, such as a plurality of qubit body wiring loops, as well as connections with or between one or more of the plurality of quantum devices.

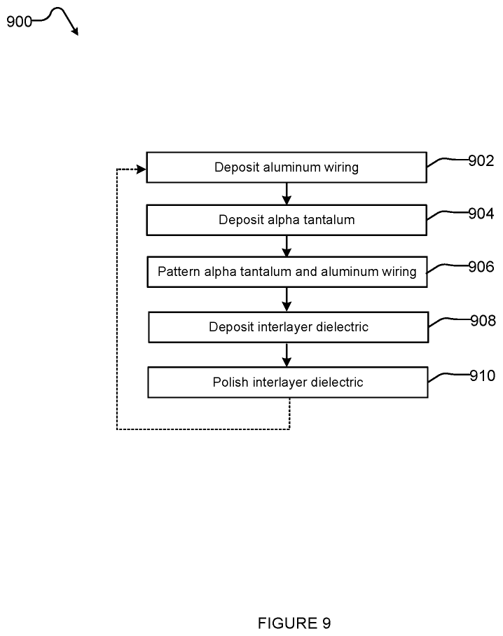

FIG. 9 is a flow chart of an example method 900 of fabricating a multi-layer integrated circuit, such as the example integrated circuit resulting from the successive fabrication stages illustrated by FIGS. 8A through 8F, in accordance with the present systems, devices, and methods. Method 900 includes acts 902-910, although in other implementations certain acts may be omitted, additional acts may be added, and/or the acts may be performed in different orders. Method 900 may be performed by, for example, integrated circuit fabrication equipment in response to an initiation of a fabrication process.

At 902, a layer of aluminum wiring is deposited as shown in the example implementation of FIG. 8A in which first layer of aluminum 804 overlies substrate 802.

At 904, a layer of a layer of α-tantalum is deposited directly onto the layer of aluminum wiring as shown in the example implementation of FIG. 8B in which first layer of α-tantalum 806 overlies first layer of aluminum 804.

At 906, the layer of α-tantalum and the layer of aluminum wiring are pattered as shown in the example implementation of FIG. 8C. As discussed above, in some implementations the deposition temperature of the layer of aluminum wiring can be controlled such that the uppers surface of the layer of aluminum wiring has an aluminum grain size that is beneficial for the growth or deposition of α-tantalum.

At 908, a dielectric layer is deposited, as shown in the example implementation of FIG. 8D in which dielectric layer 810 is deposited to overlie first layer of α-tantalum 806. In some implementations the dielectric layer may be SiOₓ, SiNₓ, a-Si, or any other suitable dielectric material as is known in the art. In some implementations, the dielectric layer may be deposited at a temperature below the melting point of aluminum. For example, in some implementations, the dielectric layer may be deposited at a temperature that is less than 650° C. In some implementations the dielectric layer may be deposited is less than 250° C., or at a temperature that is less than 100° C., or a temperature that is at or near ambient or room temperature.

At 910, the dielectric layer is polished, with the layer of α-tantalum as a polish stop, as shown in the example implementation of FIG. 8E. In some implementations, polishing the interlayer dielectric layer may involve performing chemical-mechanical polishing (CMP).

After 910, method 900 may end, or method 900 may optionally be repeated iteratively to form a multi-layer stack, as shown in the example implementation of FIG. 8F. For example, method 900 may include depositing additional layers of aluminum with overlying layers of α-tantalum to act as polish stops, such as second layer of aluminum 812 and second layer of α-tantalum 814, and additional dielectric layers, such as dielectric layer 816. Method 900 may also include patterning the respective layers to form all or a portion of a quantum processor that comprises a plurality of qubits and a plurality of couplers, such as qubits 201 and 202 and coupler 210 of FIG. 2.

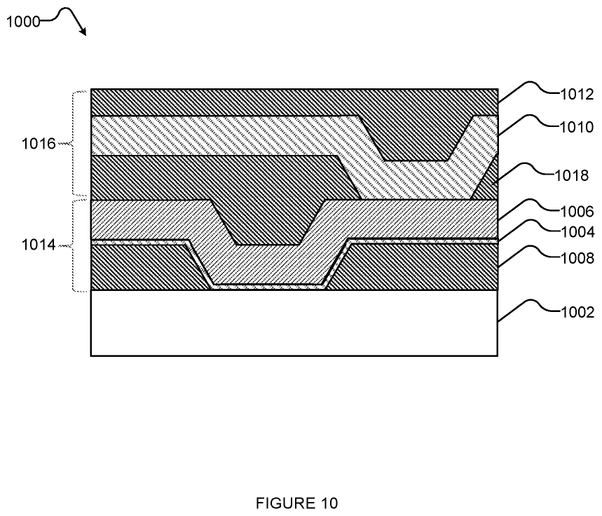

FIG. 10 is a sectional view of an example multi-layer integrated circuit 1000, in accordance with the present systems, devices, and methods. FIG. 10 has a substrate layer 1002, a seed layer of aluminum 1004 overlying substrate layer 1002, and a layer of α-tantalum wiring 1006 formed to directly overlie seed layer 1004 as discussed above, as well as dielectric layer 1008. In some implementations, substrate 1002 may be formed of silicon, sapphire, quartz, silicon dioxide, or any similar suitable material. In some implementations a similar circuit may be formed with multiple wiring layers spaced by interlayer dielectric similar to seed layer of aluminum 1004, layer of α-tantalum wiring 1006, and dielectric layer 1008. The collection of one or more wiring and dielectric layers make up an α-tantalum wiring region 1014. Overlying α-tantalum wiring region 1014 is an additional wiring region 1016. Additional wiring region 1016 includes a dielectric layer 1018 that overlies the layer of α-tantalum wiring 1006, an additional wiring layer 1010 comprising a different superconducting metal, such as one of aluminum and niobium, that overlies dielectric layer 1018, and a second dielectric layer 1012 that overlies additional wiring layer 1010. In some implementations, there may be multiple additional wiring layers wiring layers overlying α-tantalum wiring region 1014 spaced by interlayer dielectrics. In some implementations, where additional wiring layer 1010 is formed of aluminum, one or more of these aluminum wiring layers may have a polish stop layer overlying the aluminum layer, as discussed above with respect to FIGS. 8A, 8B, 8C, 8D, 8E, and 8F, and in particular with respect to the polish stop layers of layer of α-tantalum 806 and second layer of α-tantalum 814. The interlayer dielectrics may be SiOₓ, SiNₓ, a-Si, or any other suitable dielectric material known in the art. The collection of one or more additional wiring and dielectric layers may up an additional wiring region 1016.

In implementations having aluminum wiring layers in additional wiring region 1016, these additional wiring layers can, in some implementations, be formed using aluminum reflow or other fabrication techniques as described, for example, in International Publication Number WO 2021/262741.

At least one of the one or more layers of tantalum wiring (in region 1014) and at least one of the one or more layers of additional wiring (in region 1016) are in electrical communication (e.g., through vias traversing the layers) and collectively form at least one of a qubit and a coupler, such as qubits 201 and 202 and coupler 210 of FIG. 2. For example, in some implementations the body wiring for noise susceptible devices such as qubits and couplers may be placed in α-tantalum wiring region 1014, while the corresponding device Josephson junctions are formed in an additional wiring region 1016 that comprises aluminum. It will be understood that electrical vias can be formed between layers to create quantum devices. For example, the electrical traces forming the body wiring may be on a first layer with Josephson junctions on a second layer, and vias connecting the wiring to the Josephson junctions. In other implementations, the body wiring for noise susceptible devices such as qubits and couplers may be placed in α-tantalum wiring region 1014, while the corresponding device Josephson junctions are formed in an additional wiring region 1016 that comprises niobium.

The above described method(s), process(es), or technique(s) could be implemented by a series of processor readable instructions stored on one or more nontransitory processor-readable media. Some examples of the above described method(s), process(es), or technique(s) method are performed in part by a specialized device such as an adiabatic quantum computer or a quantum annealer, a gate, or circuit, model quantum computer, or a system to program or otherwise control operation of an adiabatic quantum computer, a quantum annealer, or a gate, or circuit, model quantum computer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for example purposes only and may change in alternative examples. Some of the example acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the example methods for quantum computation generally described above.

The various implementations described above can be combined to provide further implementations. All of the commonly assigned US patent application publications, US patent applications, foreign patents, and foreign patent applications referred to in this specification and/or listed in the Application Data Sheet are incorporated herein by reference, in their entirety, including but not limited to:
U.S. Pat. Nos. 7,533,068; 7,876,248; 8,035,540; 8,098,179; 8,854,074; and 9,424,526.
U.S. Provisional Patent Application No. 63/356,663.
International Publication No. WO 2021/262741.
   These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A method to form a superconducting integrated circuit comprising:
depositing a layer of aluminum;
depositing a layer of α-tantalum directly onto at least a portion of the layer of aluminum;
patterning the layer of α-tantalum and the layer of aluminum to form one or more superconducting traces; and
depositing a dielectric layer.

2. The method of claim 1, wherein depositing a layer of aluminum comprises depositing an aluminum seed layer.

3. The method of claim 2, wherein depositing a layer of α-tantalum comprises depositing a layer of α-tantalum directly onto at least a portion of the aluminum seed layer at an ambient temperature.

4. The method of claim 3, further comprising:
depositing one or more additional aluminum seed layers, one or more α-tantalum layers, and one or more dielectric layers; and
patterning the additional one or more aluminum seed layers, the additional one or more α-tantalum layers, and the additional one or more dielectric layers to form a portion of a quantum processor, the portion of a quantum processor comprising a plurality of qubits and a plurality of couplers.

5. The method of claim 1, further comprising patterning the dielectric layer.

6. The method of claim 1, wherein depositing a dielectric layer comprises depositing a dielectric layer comprising one of: SiOₓ, SiNₓ, and a-Si.

7. The method of claim 1, further comprising polishing the dielectric layer to be flush with a top surface of the layer of α-tantalum, wherein the layer of α-tantalum acts as a polish stop.

8. The method of claim 7, wherein polishing the dielectric layer comprises performing chemical-mechanical polishing.

9. The method of claim 7, further comprising:
depositing one or more additional aluminum layers, one or more α-tantalum layers, and one or more dielectric layers; and
patterning the one or more additional aluminum layers, the one or more α-tantalum layers, and the one or more dielectric layers to form a quantum processor, the quantum processor comprising a plurality of qubits and a plurality of couplers.

10. A method to form a superconducting integrated circuit, the method comprising:
depositing a layer of tantalum, the layer of tantalum comprising β-tantalum;
heating the β-tantalum of the layer of tantalum to form α-tantalum;
patterning the layer of tantalum;
depositing a dielectric layer to overlie the layer of tantalum; and
patterning the dielectric layer.

11. The method of claim 10, wherein heating the β-tantalum of the layer of tantalum to form α-tantalum comprises depositing the layer of tantalum onto a surface having a temperature greater than 500° C. for sufficient time such that such that the β-tantalum is transformed into α-tantalum as the layer of tantalum is deposited.

12. The method of claim 10, wherein heating the β-tantalum of the layer of tantalum to form α-tantalum comprises depositing the dielectric layer at a temperature greater than 500° C. for sufficient time such that the β-tantalum is transformed into α-tantalum in response to heating from the dielectric layer.

13. The method of claim 10, wherein heating the β-tantalum to form α-tantalum comprises heating the β-tantalum to a temperature greater than 500° C. for sufficient time after depositing the layer of tantalum and prior to depositing the dielectric layer.

14. The method of claim 10, further comprising performing one or more measurements of a critical temperature to confirm that the β-tantalum has transformed into the α-tantalum.

15. The method of claim 10, wherein depositing a dielectric layer comprises depositing a dielectric layer at a temperature in a range of 500° C. and 800° C.

16. The method of claim 10, wherein depositing a dielectric layer comprises depositing a dielectric layer comprising one of: SiOₓ, SiNₓ, and a-Si.

17. The method of claim 10, further comprising:
depositing one or more additional tantalum layers and one or more dielectric layers; and
patterning the one or more additional tantalum layers and one or more dielectric layers to form a quantum processor, the quantum processor comprising a plurality of qubits and a plurality of couplers.

18. A superconducting integrated circuit comprising:
a tantalum wiring region comprising:
one or more aluminum layers;
one or more layers of tantalum wiring, each layer of tantalum wiring comprising a layer of α-tantalum directly overlying a respective layer of aluminum; and
one or more first layers of dielectric.

19. The superconducting integrated circuit of claim 18, further comprising:
an additional wiring region comprising:
one or more layers of additional wiring, the one or more layers of additional wiring comprising a superconducting metal that is one of aluminum and niobium; and
one or more second layers of dielectric; and
wherein the tantalum wiring region and the additional wiring region are separated by at least one third layer of dielectric, and at least one of the one or more layers of tantalum wiring and at least one of the one or more layers of additional wiring are in electrical communication with one another and collectively form at least one of a qubit and a coupler.

20. The superconducting integrated circuit of claim 19, further comprising one or more polish stop layers directly overlying the one or more layers of additional wiring.

21. The superconducting integrated circuit of claim 18, wherein the at least one of a qubit and a coupler form a portion of a quantum processor.
